(19) United States
(12) Patent Application Publication
(10) Pub. No.: US 2002/0134399 A1
(43) Pub. Date: Sep. 26, 2002

(54) Method and apparatus for collection of lunar dust particles

(76) Inventor: Lawrence A. Taylor, Lenoir City, TN (US)

Correspondence Address: Gregory A. Nelson, Esq., Akerman, Scnterfitt & Eidson, P.A., 222 Lakeview Avenue, Suite 400, P.O. Box 3188, West Palm Beach, FL, 33402-3188, US

(21) Appl. No.: 09/813,630

(22) Filed: Mar. 21, 2001

(51) Int. Cl. B08B 6/00; B08B 7/04; H01L 31/00

(52) U.S. Cl. 134/1; 134/6; 15/1.51; 136/244; 136/291

(57) ABSTRACT

A method for collection of lunar dust particles includes the steps of providing a magnetic field source for attracting lunar dust particles, providing magnetic proximity between the lunar dust particles and the magnetic field source, and collecting lunar dust particles by the magnetic field source. An apparatus for the collection of lunar dust particles includes a magnetic field source, a structure for providing magnetic proximity between lunar dust particles and the magnetic field source, and a structure for collecting lunar dust particles by the magnetic field source. The apparatus can be utilized with a lunar living facility, such as a spaceship or lunar base. A self-cleaning solar cell includes at least one solar panel and a movable structure having a magnetic field source adapted for translation over the solar panel to collect accumulated particles.

### STATEMENT REGARDING FEDERALLY SPONSORED RESEARCH OR DEVELOPMENT

The United States Government has rights in this invention pursuant to NASA Grant No. NAG5-9158 between the United States Department of Energy and The University of Tennessee Research Corporation.

### FIELD OF THE INVENTION

This invention relates generally to a method and apparatus for particle cleaning, and specifically to a method and apparatus for the cleaning of lunar dust.

### BACKGROUND OF THE INVENTION

During man's early encounters with the lunar surface, such as the six Apollo missions, it was determined that significant concentrations of lunar soil are constantly moving in the near vacuum (approximately 10⁻¹⁴ torr) above the lunar surface. Movement of particles on the moon is greatly enhanced by the moon's ⅙˜ G environment. The moon is also extremely dry.

Lunar soil generally is fine-grained. Approximately 95% of lunar soil is finer than 1 mm, approximately 50 wt. % is finer than 60 μm in size, while approximately 10-20% is finer than 20 μm in size. Thus, lunar dust is generally comprised mainly of micro-particles. During the Apollo missions, lunar dust was found to be present to some degree on all exposed surfaces on the moon. For example, lunar dust clung to the astronaut's suits, as well to “rock boxes” used by the astronauts to collect lunar samples. It was determined that the lunar dust prevented the rock boxes that were used to bring lunar samples back to earth from being tightly sealed. In addition, the high glass content of lunar soil (up to 60 to 70 wt. %) results in lunar dust being generally highly abrasive, making it a concern for moving parts, friction bearing surfaces, and the respiratory tract (e.g. lungs) of humans.

The composition of lunar dust samples have been analyzed and found to have varying levels of magnetic properties. The amount of iron in the elemental native form (Fe°) is about 10 times greater in lunar soil than in the rocks from which the soil was formed [Taylor, 1988, Proc. Space 88, ASCE, 67; Taylor and Circlin, 1985, IONICS-ESR Dating and Dosimetry, Tokyo, 19. At first, it was assumed that this soil was meteoritic metal. However, it was later shown that the amount of meteoritic contamination in the soil is only about 2%, at most.

Lunar soil generally contains varying quantities of FeO and silicate materials. “Silicate melts” are generally formed by frequent micro-meteorite impacts with the silicate minerals in the lunar soil. The FeO in the silicate melts are auto-reduced by incident lunar hydrogen to form “nanophase” Fe°. In this mechanism, the elemental Fe° formed homogenenously nucleates into myriads of nanophase-sized (approximately 1-100 nm) Fe° particles. Upon quenching, the silicate melts form a glass which binds together the aggregates of lunar soil particles (including Fe°), which are referred to as agglutinates. The average grain size of this nanophase Fe° is substantially less than the grain size of the agglutinitic glass particles.

For a given lunar mare soil, the abundance of agglutinitic glass increases significantly with decreasing grain size, as evidenced by Is/FeO values which increase with decreasing grain size. The Is/FeO ratio, also referred to as the lunar soil-maturity index, is a standard measure of the nanophase Fe° content of a sample and is proportional to the amount of nanophase Fe°, relative to the total amount of all Fe in a given sample. The parameter Is, as used in the Is/FeO ratio, is based on electron spin resonance (ferromagnetic resonance), and measures the intensity of single domain (atomic) iron, but does not count iron atoms having non-zero oxidation states. Accordingly, a 100% increase in Is/FeO corresponds to a doubling of the amount of nanophase Fe°, relative to the total amount of Fe in a sample. Thus, the Is/FeO, ratio can be used as an indication of the amount of iron in a sample that is present as nanophase Fe°.

Lunar dust is expected to pose several major problems for many forms of activity on the moon. The high levels of glass in lunar soil makes lunar dust generally highly abrasive and a corresponding concern for moving parts and anything having a gasket, pressure seal or friction bearing surface. Living facilities are also envisioned on the moon or other extraterrestrial locations, particularly those having reasonably moderate conditions, such as temperature and atmospheric constituents. These extraterrestrial living facilities must include their own atmosphere to provide breathable air for the human occupants. It is strongly suspected that known highly abrasive lunar dust particles will be deleterious to respiratory tract of the occupants if ingested, such as inside a lunar facility. Accordingly, a system and method for cleaning of lunar dust particles is needed to permit efficient operation of lunar stations and health for their occupants. In addition, solar cells, which are expected to provide a significant portion of the energy needs for temporary habitation or at a lunar station, will likely suffer from the repeated coating of generally opaque lunar dust on solar panels, causing inefficient operation due to attenuated sunlight input.

### SUMMARY OF THE INVENTION

A method for cleaning lunar dust particles, includes the steps of providing a magnetic field source for attracting lunar dust particles, providing magnetic proximity between the lunar dust particles and the magnetic field source, and collecting lunar dust particles by the magnetic field source. The method can further include the step of utilizing the lunar dust particles to produce articles. Hot pressing of collected lunar dust particles can be used to form the articles.

The method can include the step of brushing a surface with a cleaning apparatus. The cleaning apparatus can include a magnetic source therein. The brushing step can be performed in an air shower.

A method of mining iron from the moon, includes the steps of providing a magnetic field source for attracting lunar dust particles, and collecting the lunar dust particles by the magnetic field source.

An apparatus for the collection of lunar dust particles, includes a magnetic field source for attracting lunar dust particles, structure for providing magnetic proximity between the lunar dust particles, and structure for collecting lunar dust particles by the magnetic field source.

A source of the lunar dust particles can be non-native surfaces. For example, non-native surfaces can include solar cell collectors, pressure seals and friction bearing surfaces. The lunar dust particles can have sizes of less than approximately 45 μm.

In yet another embodiment of the invention, a self-cleaning solar cell includes at least one solar panel having a surface area adapted to receive solar radiation and a movable structure having a magnetic field source adapted for translation over the surface area to collect particles accumulated on the surface area. The solar cell can operate automatically. The solar cell can further include at least one sensor for performing measurements which can be used to determine when to translate the movable structure over the surface area. The sensors can include an optical sensor. The particles collected can include lunar dust particles. The self-cleaning solar cell can be integrated into solar power satellite systems.

### BRIEF DESCRIPTION OF THE DRAWINGS

A fuller understanding of the present invention and the features and benefits thereof will be accomplished upon review of the following detailed description together with the accompanying drawings, in which:

FIG. 1 illustrates the percentage increase in Is/FeO and agglutinitic glass content between a given particle size range relative to its immediately larger size fraction for lunar soil samples.

FIG. 2 illustrates an improved particle cleaning system, according to an embodiment of the invention.

### DETAILED DESCRIPTION OF THE PREFERRED EMBODIMENTS

The high levels of glass contents of most lunar soil makes lunar dust highly abrasive and a corresponding concern for moving parts and any article having a gasket, seal (e.g. pressure seal) or friction bearing surface. As used herein, the term lunar dust will be defined to mean lunar particles having sizes of less than approximately 45 μm. Lunar dust can cause pressure seals, gaskets, moving parts and friction bearing surfaces to be damaged or fail, and can result in accelerated rates of system failures. In one embodiment of the invention, a method and apparatus for the cleaning of lunar dust particles is disclosed. The ability to effectively remove lunar dust particles provided by the invention can be used to improve the efficiency, reliability and operational lifetimes for a wide variety of devices, systems and processes which are operated on the moon or other extraterrestrial bodies.

The inventor has recently performed studies on lunar soils in order to determine the optimum conditions for the beneficiation of soil components for in-situ resource utilization (ISRU) at a lunar base [Taylor and Oder, 2000, Proc. Space 90, ASCE, 143]. Using a Frantz Isodynamic Separator, specifically calibrated for magnetic susceptibility measurements, various size fractions of several mare and highland lunar soils were studied. Soil particles were capable of beneficiation with decreasing efficiency as the grain size decreased from about 45-20 μm. However, for particle sizes<approximately 20 μm, it was determined that separation was not possible. It appeared that “clumping” of these fine-sized grains was responsible.

To attempt to understand the clumping behavior of fine-sized grains, the inventor studied the percentage increase in both Is/FeO and agglutinitic glass across a range of lunar particle sizes. [Taylor et al., 1999, New Views of the Moon II, LPI; Taylor et al., 2000, LPSC 31, LPI-CD #1697, #1706, #1842]. It was found that as the grain size of fine-grain particles decreased, a small increase in agglutinitic glass content corresponded to a much larger increase in Is /FeO values. This finding could not be explained by the conventional mechanism for formation of Fe° involving hydrogen reduction of molten FeO into elemental Fe°, homogenenous nucleation of nanophase-sized Fe°, and quenching of the melt to form agglutinitic glass.

It has been discovered that fine lunar grains contain a surface layer (patina) of ferromagnetic nanophase Fe° that results in magnetic susceptibilities of these fine grain particles substantially higher than their mineralogy would otherwise predict. For example, simply breaking larger magnetic particles into a plurality of smaller fine grain particles does not produce the enhanced levels of magnetic susceptibilities discovered. Surface-correlated nanophase Fe° layers having thicknesses of from approximately 0.1-1 μm resulting from a new mechanism, that being impact-induced vaporization and deposition of Fe and Si rich patinas, have been discovered as being responsible for coating such lunar soil particles with a patina of Fe°. It is expected that other extraterrestrial airless bodies locations having similarly thin atmospheres and significant concentrations of Fe (or other magnetic substances) will have similar ferromagnetic surface coatings on particle surfaces from impact-induced vaporization and deposition mechanisms.

The surface patinas discovered have a substantially regular thickness (0.1-1 μm), essentially irrespective of the size of the particle. Accordingly, as the size of the particle decreases, the ratio of its surface area to its volume increases, resulting in fine grained lunar dust particles having unexpectedly high magnetic energy products per unit mass.

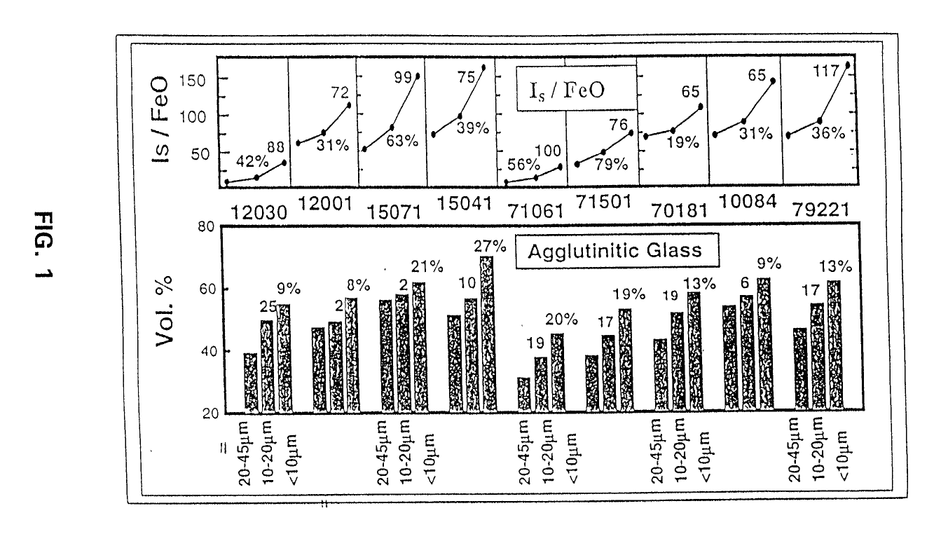

Referring to FIG. 1, the percentage increase in Is/FeO (top) and agglutinitic glass (bottom), from the larger grain size to the next smaller size fraction, is given above the respective particle size ranges. The Is/FeO values can be seen to increase with decreasing grain size. A 100% increase for Is/FeO indicates that the amount of nanophase Fe° has doubled, relative to the total Fe in the particle. It is noted that with decreasing grain size, the change in agglutinitic glass content is relatively small compared to the corresponding change in Is/FeO, which is approximately an order a magnitude greater. Thus, the rapid increase in Is/FeO with decreasing grain size is the result of another source of nanophase Fe°, in addition to the conventional mechanism believed to account for formation of Fe° involving hydrogen reduction of molten FeO into elemental Fe°, homogenenous nucleation of nanophase-sized Fe° and quenching the melt to form agglutinitic glass. The other mechanism supplying the unexplained nanophase Fe° is the vapor deposited patinas containing primarily Fe°. This mechanism only becomes a significant contributor to the mineralogy of a given lunar particle as the size of the lunar particle becomes fine-grained (e.g., lunar dust less than approximately 45 μm). For grain sizes less than approximately 45 μm, the amount of nanophase Fe° on the surface can be equal to (or greater than) the amount of nanophase Fe° in the agglutinitic glass in these fine grains.

For the same masses, the surface areas of soil increases by a factor of 4 as the grain size decreases by a factor of 2. If a portion of the increase in the Is/FeO ratio shown in FIG. 1 is attributed to the small increase in agglutinitic glass which is accounted for in each change in the grain size range, the remaining increase in the Is/FeO ratio is attributable to the surface-correlated Is/FeO contribution. On average, the data in FIG. 1 shows a 2-5× increase in Is/FeO between neighboring size fractions. For example, a decrease in grain size of 50%, results in an increase the surface area by 4× (i.e. 400%). Therefore, the increase in Is/FeO is quite comparable with the predicted 4× increase in particle surface area, confirming the presence of a vapor deposited surface nanophase Fe°. Accordingly, as the size of lunar particles begins decreasing from approximately 45 μm, its magnetic energy product per unit mass is expected to increase.

This feature of lunar dust particles permits efficient collection with magnetic attractors having relatively modest magnetic field strengths. For example, lunar dust particles of microparticle size, or even sub-micron size may be efficiently cleaned and collected from objects on or near the lunar surfaces. The ability to clean lunar dust from the objects is possible because lunar dust particles have been found to have high magnetic energy products per unit mass, due to the high percentage of Fe° in these dust particles. Larger lunar particles having the same Fe° patina, will have a far smaller energy product per unit mass, since the percentage of Fe° in the larger particle will be far smaller than a corresponding lunar dust particle. This property can be used advantageously for the magnetic cleaning and collection of fine-grained magnetic particles from any extraterrestrial location.

To clean lunar dust particles, a magnetic field source can be provided to provide an attractive force for collecting these nano- or micro-particles. The magnets used can be permanent magnets, electromagnets, or a combination of permanent magnets and electromagnets. The magnetic field source can be brought in proximity to the lunar dust particles or the lunar dust particles can be brought into proximity with the magnetic field source, as by flowing a gas stream, or these techniques can be combined.

The source of the lunar dust particles can be from the volume above the lunar surface or from a lunar surface. Surfaces can include, but are not limited to, non-native surfaces, such as telescopes, solar panels, rock-boxes, gaskets, seals and friction bearing surfaces.

Collection of lunar dust particles enables surface cleaning. The method and apparatus can be configured to select a variety of maximum particle sizes, such as less than approximately 45 μm, less than 20 μm, less than 10 μm, less than 5 μm, less than 1 μm, or even less than approximately 0.1 μm (nanoparticles). Even those dust particles that are plagioclase (mostly CaAl₂Si₂O₈ with about 5-25% NaAlSi₃O₈; both with <0.2 wt % FeO), but have a thin patina of Fe°, can be collected.

The method of collection of lunar dust particles can be performed adjacent to or within a lunar living facility. As used herein, lunar living facility includes any volume capable of supporting human life. For example, the method can support relatively temporary lunar module or a more permanent form of habitation such as a lunar base. The method can be used to reduce the airborne concentration of lunar dust particles in the breathing supply provided to occupants of a lunar living facility through use of a volume filter installed in such living facility. Alternatively, or in combination, occupants of a lunar living facility can be provided a mask filter equipped with a magnetic field source to trap lunar dust particles in the atmosphere of a lunar living facility while in the presence of significant quantities of lunar dust.

In one embodiment of the invention, a method and apparatus for the separation and collection of lunar dust utilizes high-gradient magnetic separation. High-gradient magnetic separation largely overcomes the clumping problem experienced when using conventional magnetic separation. In the high gradient magnetic separation (HGMS) technique, the material to be segregated (e.g. a mixture containing lunar dust) is passed through an open matrix of magnetic metallic material, such as steel wool, inside a magnet.

The matrix material creates locally high magnetic field gradients, which attract and trap fine particles in the approximate size range of the physical wire diameter of the matrix, while allowing larger particles to pass through. Thus, this process is the opposite of sieving, where the larger particles are trapped while smaller particles pass through the sieve.

By using a plurality of matrix wire diameter sizes stacked serially beginning with the finest wire diameter, it is possible to segregate raw material having a mixture of particle sizes into a plurality of different size ranges. When the matrix material becomes largely saturated, the magnetic field can be turned off (e.g. by removing the current to the electromagnet), or the matrix material can be mechanically removed to a location outside the magnetic field source, where the particles collected on the matrix material can be released and directed to a selected destination, such as a container to await a future use.

On earth, HGMS is generally performed in a water slurry, such as in the kaolin industry, which annually processes many tons of clay each year. However, because there is essentially no atmosphere on the moon, it may be possible to process lunar soil using HGMS without the need for a working fluid.

In one embodiment of the invention, a surface can be cleaned by using a sweeping or brushing device. A wand can also be used. These devices can each include a magnetic field source positioned therein or disposed in an adjacent position. In a related method, a method for cleaning and collecting lunar dust particles includes the steps of moving a magnetic source in proximity to a plurality of lunar dust particles disposed on a surface, and attracting said lunar dust particles to the magnetic source.

Air showers or similar apparatus can be used in or around entrances to extraterrestrial facilities such as lunar facilities to remove particles. Structures similar to conventional air shower can be used with the invention. A modified air shower in accordance with an embodiment of the invention includes a brushing apparatus combined with an air shower having at least one air lock, or a similar apparatus, where a brushing step can be performed in an air shower to enhance particle removal and permit optional collection of particles including dust particles, from objects, such as an individual, positioned in the air shower. This embodiment provides an air shower apparatus capable of improving the efficiency with which lunar dust particles can be removed, preventing dust particles from becoming re-attached and preventing air mixed with dust particles from leaking into a volume containing breathable air in an extraterrestrial facility, such as a lunar facility. Removal of lunar dust particles during air showering can reduce the airborne concentration of potentially harmful dust particles, such as abrasive glass containing particles. The air shower can preferably be located all entrances to any volume which provides breathing air, such as a lunar living facility.

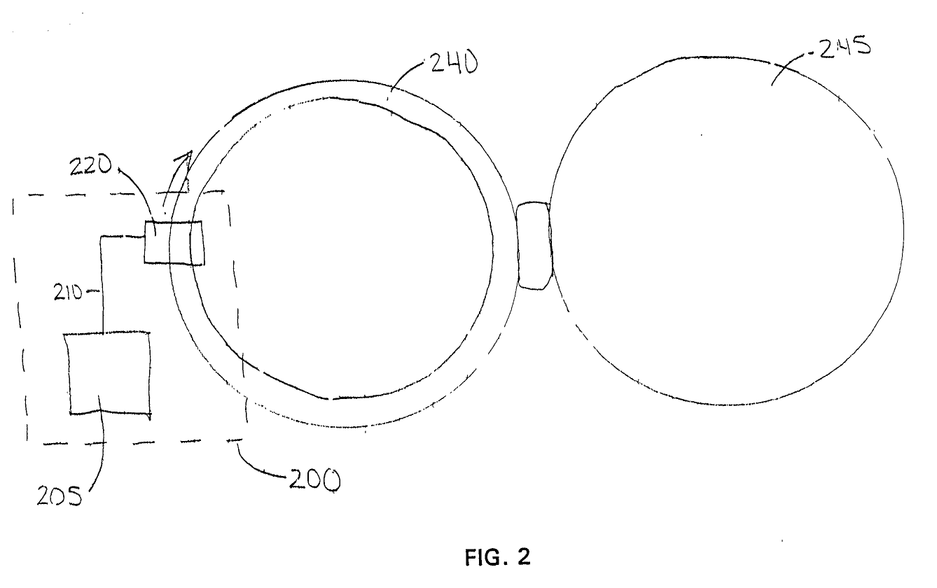

In another embodiment of the invention, an improved particle cleaning system 200 is shown in FIG. 2 adapted to remove lunar dust particles from surfaces, such as a door seal 240 of a lunar module (not shown). Seal 240 permits lid 245 to close on top of seal 240 to protect the occupants and contents of lunar module (not shown) from harsh outside influences. Cleaning system 200 comprises a motor 205 which drives arm 210 which is attached to magnetic source 220. Magnetic source 220 may be a permanent magnet or electromagnet, or combine both magnet types.

Once commanded to begin cleaning, either through automatic controls (not shown) or a manual switch (not shown), magnetic source 220 can begin translation across a surface to be cleaned, such as seal 240. Lunar dust particles, having high magnetic energy densities per unit mass are readily attracted to magnetic source 220. Alternatively, or in combination, a permanent magnet (not shown) may be placed adjacent to a surface to be cleaned, such as seal 240, to limit the number of dust particles that are deposited on seal 240, the dust particles being preferentially deposited on adjacent permanent magnet (not shown). In the case of an electromagnet embodiment of magnetic source 220, shutting of the current to the electromagnet permits simple purging of collected particles from magnetic source 220. Similarly, cleaning system can be easily adapted to clean lunar dust particles from exposed surfaces such as friction bearing surfaces and solar cells.

The invention can be used with solar power satellite systems to remove accumulated dust particles on solar panels, many of which are magnetic due to their space-weathering origins. Solar power satellites are large-scale power plants based in space which move in geosynchronous orbits. The satellites could be in the sunlight for over 99% of the year. They would only pass through the shadow of the earth for brief periods during the spring and fall equinoxes. Electric energy could be generated by vast arrays of solar cells which convert sunlight to electricity. The electricity could be routed to a phased array transmitting antenna that could convert the electricity into radio frequency energy and transmit the energy in a wireless power transmission beam to an earth-based receiver. This type of receiver, called a rectenna, could convert the radio frequency back into DC electricity. Power processors would then convert the DC electricity to AC power for distribution on existing power grids.

In yet another embodiment of the invention, a method for mining particles having high elemental Fe contents on the moon is disclosed. These particles may be particularly useful due to their patina of iron coated on their surfaces. Lunar soil can first be separated by size using separation devices that are well known in the art, such as a HGMS. The magnetic field source can be used to select the particles based on their ability to be attracted to the magnetic field provided. This method preferentially collects lunar dust particles having higher percentages of Fe° from the other lunar particles which may be provided in a lunar sample. Mining efficiency can be enhanced in certain mining applications through use of a structure for creating turbulence in the lunar or extraterrestrial soil.

Unprocessed lunar dust may be useful for a wide range of applications based on its unique structure and corresponding magnetic properties. Lunar dust has been found to have super-paramagnetic properties resulting from associated Fe° patinas. Similar particles may be difficult or nearly impossible to form. Numerous applications in the electronics and magnetic industries, such as in the formation of superconductors, is anticipated.

These fine lunar dust particles, along with the high-magnetic susceptibility agglutinitic glasses from coarser sizes can be easily beneficiated from the lunar soil to make a feedstock for forming articles. The Fe° present both on the particle surfaces, as well as in the agglutinitic glasses, can be easily formed into articles by annealing (e.g., by conventional or microwave heating) at temperatures of approximately 1000° C. or higher. This can render lunar dust particles a valuable feedstock from which to retrieve Fe, even by rather crude magnetic separation. Larger magnets are expected to be more efficient collectors. It will be possible to easily shape and form the collected soil and to sinter it by techniques known in the art such as “hot pressing.” The nanophase Fe° can grow during this process, which can add significantly to the adhesion and strength of the aggregates formed. In addition, the nanophase Fe° which is located within a silicate glass, which being inherently unstable, will readily add addition fusion of the nanophase Fe° particles to each other. Thus, the discovery of the abundance of nanophase native Fe on the surface of lunar soils has potential for numerous uses for in-situ resource utilization (ISRU) at remote locations, such as lunar bases.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as described in the claims.

I claim:

1. A method for cleaning lunar dust particles, comprising the steps of:
providing a magnetic field source for attracting lunar dust particles;
providing magnetic proximity between said lunar dust particles and said magnetic field source, and
collecting said lunar dust particles by said magnetic field source.

2. The method of claim 1, wherein a source of said lunar dust particles are from non-native surfaces being at least one selected from the group consisting of solar panels, pressure seals and friction bearing surfaces.

3. The method of claim 1, wherein said lunar dust particles have sizes of less than approximately 45 μm.

4. The method of claim 1, further comprising the step of hot pressing said collected lunar dust particles to form articles.

5. The method of claim 1, wherein said method is performed within a lunar living facility.

6. The method of claim 1, further comprising the step of brushing a surface with a cleaning apparatus.

7. The method of claim 6, wherein said cleaning apparatus includes a magnetic source therein.

8. The method of claim 7, wherein said brushing step is performed in an air shower.

9. A method of mining iron from the moon, comprising the steps of:
providing a magnetic field source for attracting lunar dust particles;
moving said magnetic field source, wherein said lunar dust particles are collected by said magnetic field source; and
removing said collected lunar particles from said magnetic field source.

10. An apparatus for the collection of lunar dust, comprising:
a magnetic field source for lunar dust particles;
structure for providing magnetic proximity between said magnetic field source and said lunar dust particles, and
structure for collecting said lunar dust particles by said magnetic field source.

11. The apparatus of claim 10, wherein a source of said lunar dust particles is from non-native surfaces being at least one selected from the group consisting of solar panels, pressure seals and friction bearing surfaces.

12. The apparatus of claim 10, wherein said lunar dust particles have sizes of less than approximately 45 μm.

13. The apparatus of claim 10, further comprising a structure for utilizing said collecting lunar dust particles to produce articles.

14. The apparatus of claim 13, further comprising a structure for hot pressing said collected lunar dust particles to form said articles.

15. The apparatus of claim 10, wherein said apparatus is utilized in a lunar living facility.

16. The apparatus of claim 10, further comprising a brush for brushing a surface having said lunar dust particles thereon.

17. The apparatus of claim 16, wherein said brush includes a magnetic source therein.

18. The apparatus of claim 17, wherein said brush is used in an air shower.

19. A method for cleaning and collection of lunar dust particles from surfaces, comprising the steps of:
moving a magnetic source in proximity to a plurality of lunar dust particles disposed on a surface, and
attracting said lunar dust particles to said magnetic source.

20. The method of claim 19, wherein said surface includes a friction bearing surface.

21. The method of claim 19, wherein said dust particles have sizes of less than approximately 45 μm.

22. A method for cleaning surfaces having extraterrestrial particles thereon, comprising the steps of:
providing a magnetic field source for attracting extraterrestrial particles;
providing magnetic proximity between said extraterrestrial particles and said magnetic field source, and
collecting said extraterrestrial particles by said magnetic field source.

23. A self-cleaning solar cell, comprising,
at least one solar panel having a surface area adapted to receive solar radiation, and
a movable structure having a magnetic field source adapted for translation over said surface area to collect particles accumulated on said surface area.

24. The self-cleaning solar cell of claim 23, wherein said structure operates automatically.

25. The self-cleaning solar cell of claim 23, further comprising at least one sensor for performing measurements, said measurements used to determine when to translate said movable structure over said surface area.

26. The self-cleaning solar cell of claim 23, wherein said sensors include an optical sensor.

27. The self-cleaning solar cell of claim 23, wherein said particles collected include lunar dust particles.

28. The self-cleaning solar cell of claim 23, wherein said self-cleaning solar cell is integrated into a solar power satellite system.
